(19) United States
(12) Patent Application Publication
(10) Pub. No.: US 2009/0284933 A1
(43) Pub. Date: Nov. 19, 2009

(54) COMBINATION TYPE HEAT DISSIPATION MODULE

(75) Inventors: PIN-CHUN CHEN, TAIPEI CITY (TW); HSI-KU TU, TAICHUNG CITY (TW); SHANG-WU CHEN, KINMEN COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: EDISON OPTO CORPORATION, TAIPEI HSIEN (TW)

(21) Appl. No.: 12/121,130

(22) Filed: May 15, 2008

(51) Int. Cl. H05K 7/20

(52) U.S. Cl. 361/722

(57) ABSTRACT

A combination type heat dissipation module applied to dissipate at least one heat source is disclosed. The combination type heat dissipation module comprises a heat dissipation base and a plurality of heat dissipation cells. A base heat conduction surface of the heat dissipation base is applied to connect the heat source, a plurality of assembling grooves are recessed from a base heat dissipation surface of the heat dissipation base, and a cell body of each heat dissipation cell has a cell heat dissipation surface. At least two of the heat dissipation cells are respectively assembled to at least two of the assembling grooves, and keep their cell heat dissipation surfaces being exposed from the base heat dissipation surface.

### FIELD OF THE INVENTION

The present invention relates to a heat dissipation module, and more particularly to a combination type heat dissipation module manufactured by assembling a plurality of heat dissipation cells to a heat dissipation base.

### BACKGROUND OF THE INVENTION

In the daily life, many electronic components, such as lighting emitting diodes (LED), or central processing unit (CPU), etc. are applied to be installed within many electrical or electronic devices. The electronic components usually continuously release heat energy to form heat sources when they are under working. In many conditions, the heat sources do cause many negative influences, such as lowering broken loading, decreasing life of use, slowing down the working speed, decreasing the working efficiency, etc., to the electrical or electronic devices.

Therefore, in the electrical or electronic devices, at least one heat dissipation module is usually assembled to the heat sources to dissipate heat energy. Among the existing heat dissipation modules, most are provided to increase heat dissipation efficiency through two aspects; one is material, and the other is structure. In material aspect, the heat dissipation module has to be made of the material with high heat conduction coefficient, so as to increase the efficiency of heat conduction; and in structure aspect, the heat dissipation module has to be provided with larger surface area, so as to increase the efficiency of heat exchange between the heat dissipation module and external environment. Under the background, most of the existed heat dissipation modules are made by forming a plurality of heat dissipation fins extended from a heat dissipation base, so as to increase the overall surface area to further upgrade the efficiency of heat exchange.

Practically, the heat energy released from different kinds of heat source may be different due to the influence of many factors, such as environment temperature, working voltage, working current, working power or working speed, etc. Thus, it is necessary to provide different heat dissipation modules with different heat dissipation efficiencies so as to match the heat dissipation requirements of different heat sources.

However, the existed heat dissipation modules, most are only provided in single specified structure, so that the properties and the efficiencies of heat dissipation of the existed heat dissipation modules cannot be adjusted any more when assembled with different heat sources. At most, a method of using two or more heat dissipation modules to be assembled with the heat dissipation module may be carried out to solve the problem. Even that, there are still many limitations and difficulties existing in the method as mentioned, such as the limitation of contact area between the two or more heat dissipation modules and the heat source(s), and the difficulty of finely adjusting the properties and the efficiencies of heat dissipation.

Based on above description, the inventor is of the opinion that it is necessary to develop a new heat dissipation module, so as to finely adjust the properties and the efficiencies of heat dissipation of the new heat dissipation module, in accordance with heat energy released from the heat source and the heat energy distribution, under a condition that without changing the area being allowable to contact with the heat source(s).

### SUMMARY OF THE INVENTION

Due to that the heat dissipation module provided in prior arts cannot solve the problems as mentioned; a primary objective of the present invention provides a combination type heat dissipating module manufactured by assembling a plurality of heat dissipation cells to a heat dissipation base. Therefore, under a condition that does not change the area of the heat dissipation base being allowable to contact with the heat source(s), it is able to finely adjust the properties and the efficiencies of heat dissipation of the combination type heat dissipation module, in accordance with heat energy released from the heat source and the heat energy distribution, through the method of adjusting the assembling amount and the assembling type of the heat dissipation cells.

Means of the present invention for solving the problems as mentioned above provides a combination type heat dissipation module, which is applied to dissipate at least one heat source. The combination type heat dissipation module comprises a heat dissipation base and a plurality of heat dissipation cells. A base heat conduction surface of the heat dissipation base is applied to connect the heat source, a plurality of assembling grooves are recessed from a base heat dissipation surface of the heat dissipation base, and a cell body of each heat dissipation cell has a cell heat dissipation surface. At least two of the heat dissipation cells are respectively assembled to at least two of the assembling grooves, and keep their cell heat dissipation surfaces being exposed from the base heat dissipation surface.

Except for assembling heat dissipation cells to the heat dissipation base, in two preferred embodiments of the present invention, another assembling type, which assembles the heat dissipation cell(s) to the other heat dissipation cell(s), is disclosed as follows. In said two preferred embodiments, the cell body can be further formed with a receiving groove recessed from the cell heat dissipation surface, and the cell body of at least one of the heat dissipation cells is assembled into the receiving groove of another one of the heat dissipation cells.

Comparing with the conventional heat dissipation module as disclosed in prior arts, under the condition that does not change the area of the heat dissipation base being allowable to contact with the heat source(s), in the combination type heat dissipation module of the present invention, it is able to finely adjust the properties and the efficiencies of heat dissipation of the combination heat dissipation module, in accordance with heat energy released from the heat source and the heat energy distribution, through the method of adjusting the assembling amount and the assembling type of the heat dissipation cells. Moreover, it is more obviously that the combination type heat dissipation module of the present invention not only can provide more possible selections for heat dissipation, but also can further save the cost of manufacturing many kinds of heat dissipation modules fitting for different heat sources.

The devices, characteristics, and the preferred embodiment of this invention are described with relative figures as follows.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 illustrates a heat dissipation base being applied to be assembled with three heat dissipation cells and a heat source in a first embodiment of the present invention;

FIG. 2 illustrates a perspective view of the heat dissipation cell in the first embodiment of the present invention;

FIG. 3 illustrates the heat dissipation cell formed with a plurality of heat dissipation fins and outer-curved plates in the first embodiment of the present invention;

FIG. 4 is a perspective view illustrating that the combination type heat dissipation nodule is assembled with the heat source in the first embodiment of the present invention;

FIG. 5 illustrates the assembling amount and the assembling type of the heat dissipation cells can be changed for fitting the heat source assembling to different position of the heat dissipation base in a second embodiment of the present invention;

FIG. 6 is a perspective view illustrating that the combination type heat dissipation module is assembled with the heat source in the second embodiment of the present invention;

FIG. 7 illustrates the assembling amount and the assembling type of the heat dissipation cells can be changed for fitting the heat source releasing more heat energy under working in a third embodiment of the present invention; and

FIG. 8 is a perspective view illustrating that the combination type heat dissipation module is assembled with the heat source in the third embodiment of the present invention.

### DETAILED DESCRIPTION OF THE PREFERRED EMBODIMENTS

The combination type heat dissipation module as provided in accordance with the present invention can finely adjust the properties and the efficiencies of heat dissipation of the combination type heat dissipation module, in accordance with heat energy released from the heat source and the heat energy distribution, through the method of adjusting the assembling amount and the assembling type of the heat dissipation cells, so that it can be widely applied to dissipate heat energy released from many kinds of heat sources. Obviously, the combined applications of the present invention are too numerous to be enumerated and described, so that on the basis of the structure, only three preferred embodiments applied to dissipate heat energy released from light emitting diode light assemblies are disclosed as follows for representation.

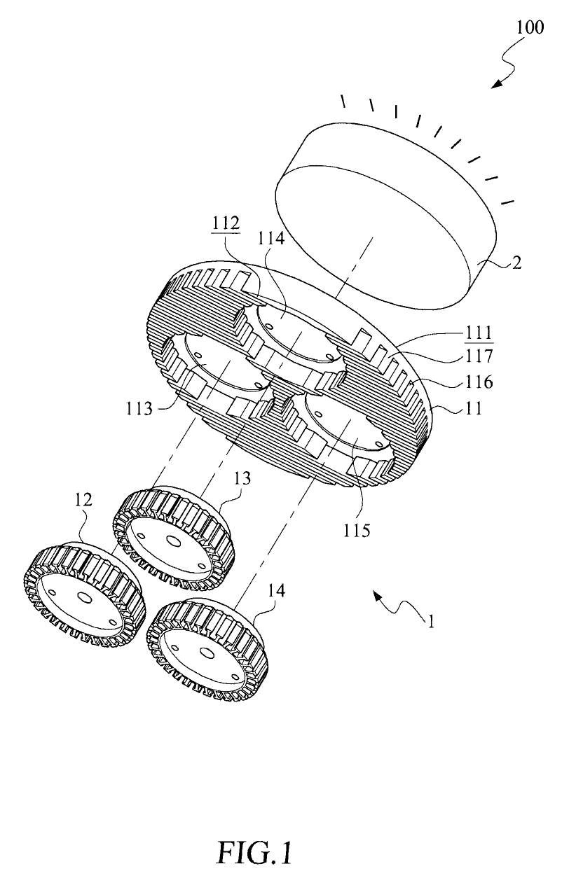

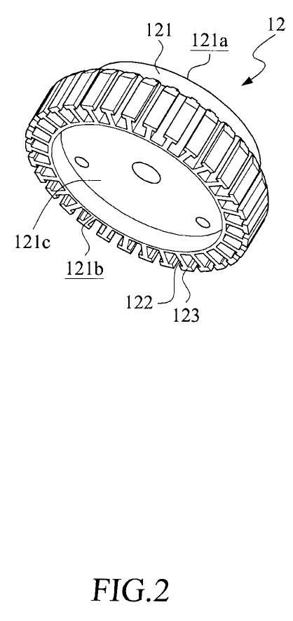

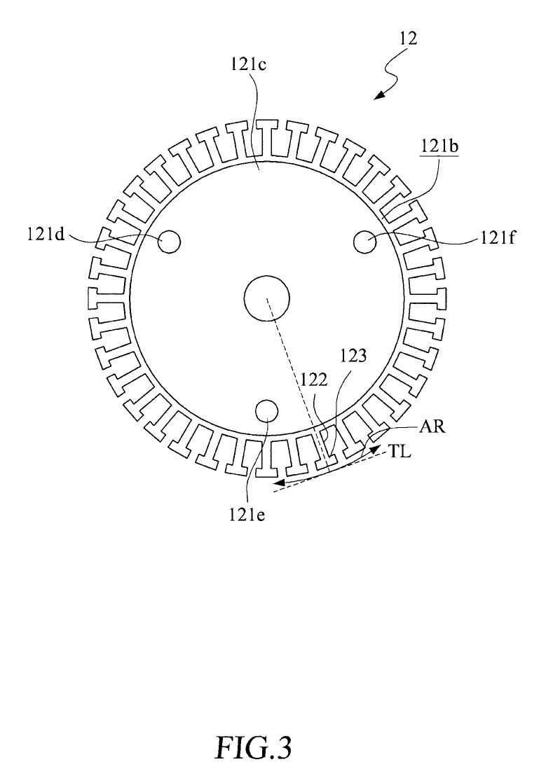

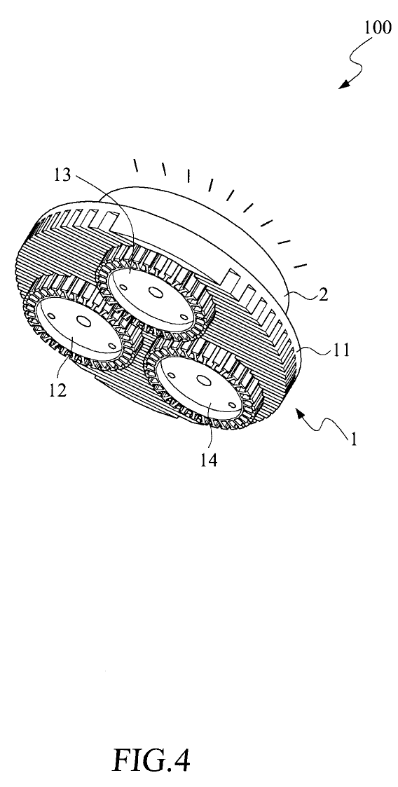

Please refer to FIG. 1 to FIG. 4, wherein FIG. 1 illustrates a heat dissipation base being applied to be assembled with three heat dissipation cells and a heat source in a first embodiment of the present invention; FIG. 2 illustrates a perspective view of the heat dissipation cell in the first embodiment of the present invention; FIG. 3 illustrates the heat dissipation cell formed with a plurality of heat dissipation fins and outer-curved plates in the first embodiment of the present invention; and FIG. 4 is a perspective view illustrating that the combination type heat dissipation nodule is assembled with the heat source in the first embodiment of the present invention. As shown in the associated figures, a combination type heat dissipation module (hereinafter being simplified by “heat dissipation module”) 1 is applied to be assembled with a heat source, so as to dissipate heat energy released from the heat source. In the first embodiment of the present invention, the heat source implies a light emitting diode (LED) light assembly 2 which releases heat energy when working, and the heat dissipation module 1 is assembled with the LED assembly 2 to form an illumination device 100.

The heat dissipation module 1 comprises a heat dissipation base 11 and three heat dissipation cells 12, 13 and 14. The heat dissipation cell 11 has a base heat conduction surface 111, a base heat dissipation surface 112, three assembling grooves 11, 12, 13, a plurality of heat guiding groove 116 and a plurality of heat dissipation ribs 117. The base heat conduction surface 111 is applied to be assembled with the LED assembly 2; the base heat dissipation surface 112 is opposite to the base heat conduction surface 111; the assembling grooves 113, 114 and 115 are recessed from the base heat dissipation surface 112 for assembling the heat dissipation cells 12, 13 and 14 thereto; the heat guiding grooves 116 are recessed from the base heat dissipation surface 112 and extended parallel with each other; and each of the heat dissipation ribs 117 is formed between any neighboring two of the heat guiding grooves 116.

The heat dissipation cell 12 comprises a cell body 121, a plurality of heat dissipation fins 122 and a plurality of outer-curved plates 123. The cell body 121 has a cell heat conduction surface 121a, a cell heat dissipation surface 121b, a receiving groove 121c, three connection holes 121d, 121e and 121f. The cell heat dissipation surface 121b is opposite to the cell heat conduction surface 121a; the receiving groove 121c is recessed from the heat dissipation surface 121b; and the connection holes are bored from the receiving groove 121c to the cell heat conduction surface 121a for the connection members, such as bolts or pins, etc., perforating through, so as to further fix the heat dissipation cell 12 onto the heat dissipation base 11. After the heat dissipation cell being assembled to the receiving groove 121c, the cell heat conduction surface 121a is located within the receiving groove 121c, and the cell heat dissipation surface 121b is exposed from the base heat dissipation surface 112.

The heat dissipation fins 122 are outwardly and radially extended from the cell body; and the outer-curved plates 123 are separated from each other and distributed in a ring distribution. Each of the outer-curved plates 123 is extended along an arc path AR; each of the heat dissipation fins 122 is outwardly and radially extended to the respected one of the outer-curved plates 123, and a tangent line TL of the arc path AR is vertical to one of the heat dissipation fins 122. Due to that the structures of the heat dissipation cells 13 and 14 are similar to or the same as the structure of the heat dissipation cell 12, the detail description of the heat dissipation cells 13 and 14 is skipped hereunder.

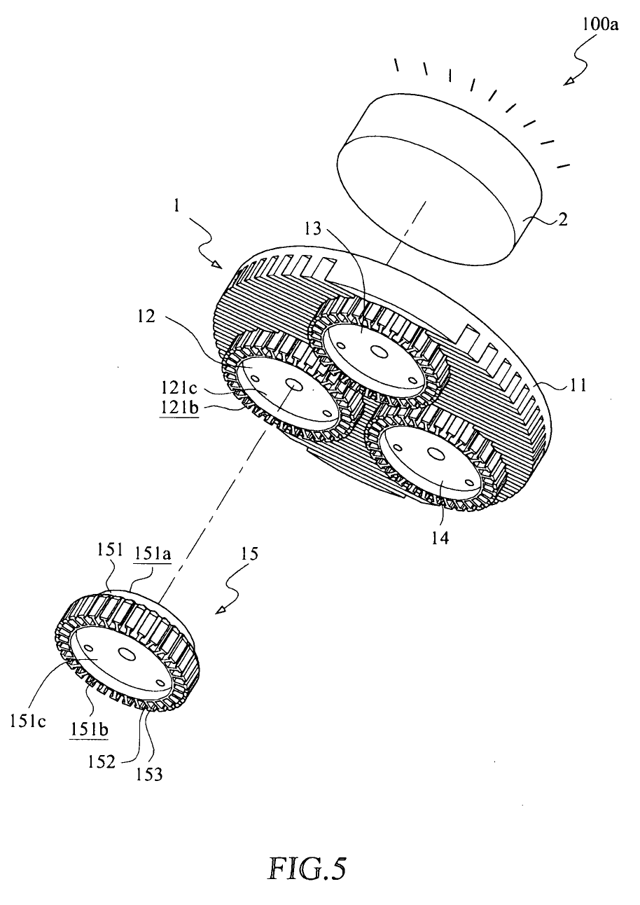

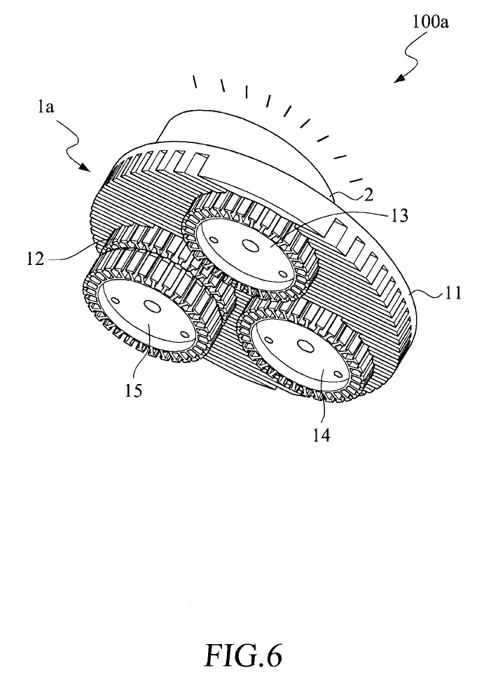

Please refer to FIG. 5 and FIG. 6, wherein FIG. 5 illustrates the assembling amount and the assembling type of the heat dissipation cells can be changed for fitting the heat source assembling to different position of the heat dissipation base in a second embodiment of the present invention; and FIG. 6 is a perspective view illustrating that the combination type heat dissipation module is assembled with the heat source in the second embodiment of the present invention. As shown in the associated figures, another combination type heat dissipation module (hereinafter being simplified by “heat dissipation module”) 1a is made by assembling a heat dissipation cell 15 to the heat dissipation module 1. The heat dissipation module 1a is also applied to be assembled with a heat source, so as to dissipate heat energy released from the heat source. In the second embodiment of the present invention, the heat source also implies the light emitting diode (LED) light assembly 2 which releases heat energy when working, and the heat dissipation module 1a is assembled with the LED assembly 2 to form another illumination device 100a.

The heat dissipation cell 15 comprises a cell body 151, a plurality of heat dissipation fins 152 and a plurality of outer-curved plates 153. The cell body 151 has a cell heat conduction surface 151a, a cell heat dissipation surface 151b, a receiving groove 151c, and three connection holes (element numbers are not given). Due to that the overall structure of the heat dissipation cell 15 is similar to or the same as that of the heat dissipation cells 12, the detail description of the heat dissipation cells 15 is also skipped hereunder.

From FIG. 5 and FIG. 6, in the second embodiment of the present invention, due to that the LED assembly 2 is assembled to the heat dissipation base in a region near the heat dissipation cell 12, the distribution of heat energy released from the LED assembly 2 under working is changed with respect to the first embodiment. Obviously, in the region near the heat dissipation cell 12, more heat energy is absorbed to generate higher temperature, so that it is necessary to be provided with higher heat dissipation efficiency in the region near the heat dissipation cell 12. Under this basis, it is able to assemble the cell body 151 of the heat dissipation cell 15 to the receiving groove 121c of the cell body 121 of the heat dissipation cell 121, so as to make the region near the heat dissipation cell 12 perform higher heat dissipation efficiency.

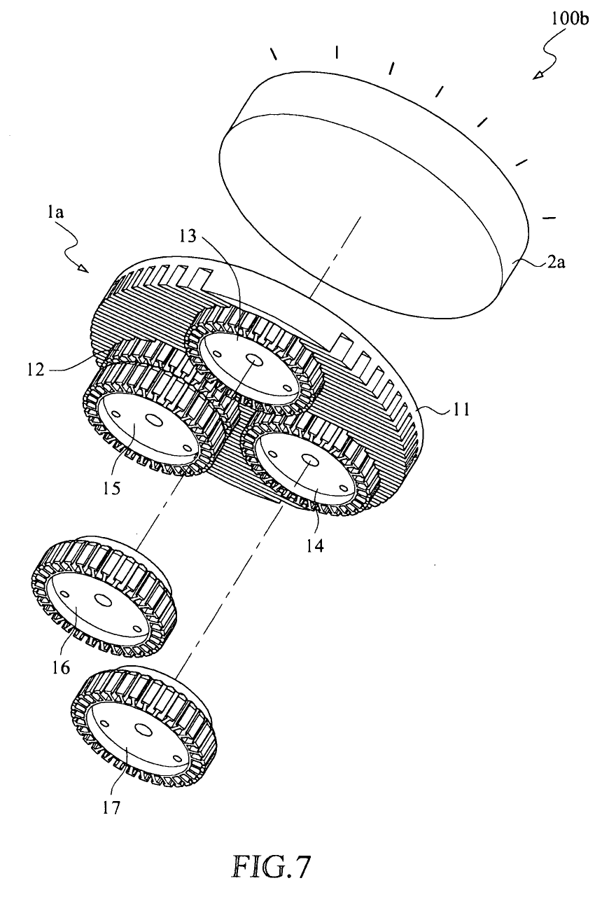

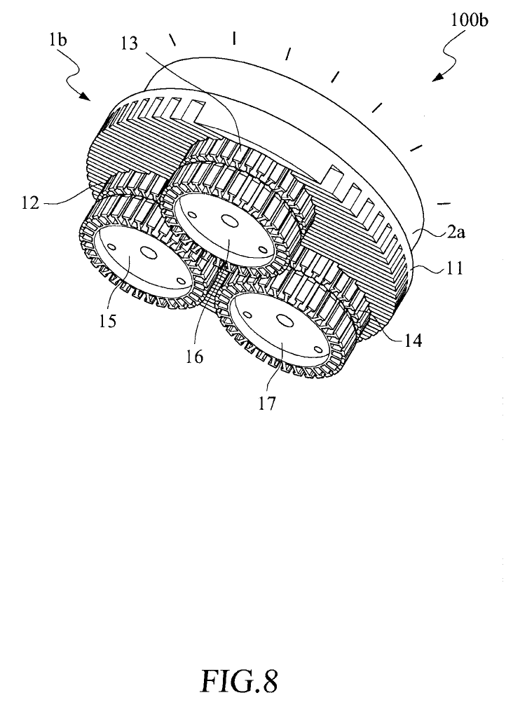

Please refer to FIG. 7 and FIG. 8, wherein FIG. 7 illustrates the assembling amount and the assembling type of the heat dissipation cells can be changed for fitting the heat source releasing more heat energy under working in a third embodiment of the present invention; and FIG. 8 is a perspective view illustrating that the combination type heat dissipation module is assembled with the heat source in the third embodiment of the present invention. As shown in the associated figures, another combination type heat dissipation module (hereinafter being simplified by “heat dissipation module”) 1b is made by assembling heat dissipation cells 16 and 17 to the heat dissipation module 1a. The heat dissipation module 1b is also applied to be assembled with a heat source, so as to dissipate heat energy released from the heat source. In the third embodiment of the present invention, the heat source here implies another light emitting diode (LED) light assembly 2a which releases more heat energy under working, and the heat dissipation module 1b is assembled with the LED assembly 2a to form another illumination device 100b, wherein the structures of heat dissipation cells 16 and 17 are similar to or the same as the structure of the heat dissipation cell 12.

From FIG. 7 and FIG. 8, with comparison to the first embodiment, in the third embodiment of the present invention, the LED assembly 2a releases more heat energy under working. Obviously, it is necessary to assemble another heat dissipation module with higher heat dissipation efficiency. Under this background, it is able to assemble another two heat dissipation cells 16 and 17 respectively to the heat dissipation cells 13 and 14 in accordance with the assembling method of the heat dissipation cell 15 as mentioned, so as to manufacture to the heat dissipation module 1b and make the heat dissipation module 1b perform higher heat dissipation efficiency.

After reading above three preferred embodiments of the present invention, it is believable that any person skilled in ordinary arts cannot but admitting the facts as follows. Due to that he combination type heat dissipation module is manufactured by assembling the heat dissipation cells to the heat dissipation base; therefore, under the condition that does not change the area of the heat dissipation base being allowable to contact with the heat source(s), in the combination type heat dissipation module of the present invention, it is able to finely adjust the properties and the efficiencies of heat dissipation of the combination heat dissipation module, in accordance with heat energy released from the heat source and the heat energy distribution, through the method of adjusting the assembling amount and the assembling type of the heat dissipation cells. Moreover, it is more obviously that the combination type heat dissipation module of the present invention not only can provide more possible selections for heat dissipation, but also can further save the cost of manufacturing many kinds of heat dissipation modules fitting for different heat sources.

Additionally, in the present invention, due to that the heat dissipation cell 12 is formed with the outer-curved plates 123; thus, when the user holds the heat dissipation cell 12, it able to prevent the user from being hurt by sharp burrs, which are generated when manufacturing the heat dissipation cell 12.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A combination type heat dissipation module applied to dissipate heat from at least one heat source, and comprising:
a heat dissipation base having a base body, and the base body comprising:
a base heat conduction surface for connecting the heat source;
a base heat dissipation surface opposite to the base heat conduction surface, and recessed with a plurality of assembling grooves; and
a plurality of heat dissipation cells, each comprising a cell body having a cell heat dissipation surface;
wherein at least two of the heat dissipation cells are respectively assembled to at least two of the assembling grooves, and keep their cell heat dissipation surfaces being exposed from the base heat dissipation surface.

2. The combination type heat dissipation module as claimed in claim 1, wherein the cell body is further bored with at least one connection hole.

3. The combination type heat dissipation module as claimed in claim 1, wherein the cell body is further formed with a receiving groove recessed from the cell heat dissipation surface.

4. The combination type heat dissipation module as claimed in claim 3, wherein the cell body of at least one of the heat dissipation cells is assembled to the receiving groove of another one of the heat dissipation cells.

5. The combination type heat dissipation module as claimed in claim 4, wherein the cell body is further bored with at least one connection hole perforating the cell body from the receiving groove to the cell heat conduction surface.

6. The combination type heat dissipation module as claimed in claim 1, wherein the heat dissipation base further comprises a plurality of heat guiding grooves recessed from the base heat dissipation surface, each one of the heat guiding grooves is separated from another one of the heat guiding grooves, such that a heat dissipation rib is formed between any two neighboring ones of the heat guiding grooves.

7. The combination type heat dissipation module as claimed in claim 6, wherein the heat guiding grooves are extended parallel with each other.

8. The combination type heat dissipation module as claimed in claim 1, wherein each of the heat dissipation cells further comprises a plurality of heat dissipation fins outwardly and radially extended from the cell body.

9. The combination type heat dissipation module as claimed in claim 8, wherein each of the heat dissipation cells further comprises a plurality of outer-curved plates, each of the outer-curved plates is extended along an arc path, and each of the heat dissipation fins is outwardly and radially extended to one of the outer-curved plates.

10. The combination type heat dissipation module as claimed in claim 9, wherein a tangent line of the arc path is vertical to one of the heat dissipation fins.

11. The combination type heat dissipation module as claimed in claim 9, wherein the outer-curved plates are separated from each other and distributed in a ring distribution.
